(19) United States
(12) Patent Application Publication
(10) Pub. No.: US 2026/0196268 A1
(43) Pub. Date: Jul. 9, 2026

(54) COMPUTING BIT CELL, DEVICE INCLUDING THE SAME AND METHOD OF OPERATION THEREOF

(71) Applicant: SAMSUNG ELECTRONICS CO., LTD., Suwon-si (KR)

(72) Inventors: Kyeongho LEE, Suwon-si (KR); Jongsun PARK, Seoul (KR); Junwoo PARK, Seoul (KR); Hyunjun KIM, Suwon-si (KR)

(73) Assignees: SAMSUNG ELECTRONICS CO., LTD., Suwon-si (KR); KOREA UNIVERSITY RESEARCH AND BUSINESS FOUNDATION, Seoul (KR)

(21) Appl. No.: 19/338,366

(22) Filed: Sep. 24, 2025

(30) Foreign Application Priority Data
Jan. 6, 2025 (KR) 10-2025-0001807
Apr. 22, 2025 (KR) 10-2025-0052137

(51) Int. Cl. G11C 16/04; G11C 16/20; G11C 16/30

(52) U.S. Cl. CPC G11C 16/0433; G11C 16/20; G11C 16/30

(57) ABSTRACT

A device includes a computing bit cell, and a control circuit that controls the computing bit cell. The computing bit cell includes a memory cell that stores a coefficient bit and first to third transistors. The first transistor is connected between a first node and a ground node and has a gate that is connected to a first line which extends in a first direction and which receives a voltage based on a first input bit. The second transistor is connected between a second node and a second line that extends in a second direction that crosses the first direction, the second transistor having a gate that receives a pre-charge enable signal, the second line receiving a voltage based on a second input bit. The third transistor is connected between the first node and the second node and has a gate connected to the memory cell.

### CROSS-REFERENCE TO RELATED APPLICATIONS

This application claims priority to Korean Patent Application No. 10-2025-0001807, filed on Jan. 6, 2025, and to Korean Patent Application No. 10-2025-0052137, filed on Apr. 22, 2025, in the Korean Intellectual Property Office, the disclosures of each of which being incorporated by reference herein in their entireties.

### BACKGROUND

Example embodiments relate to a memory for computation, and more specifically, to a computing bit cell, a device including the same, and a method of operation thereof.

A system for computation may include a memory and a processing unit. For example, a hardware accelerator designed for high-speed computation may include processing elements and a high-speed memory accessible to the processing elements. Energy consumed in transferring data between memory and the processing elements may outweigh the energy consumed in processing data in applications, such as artificial neural networks, that need to process a large number of parameters. For this reason, in-memory computing or compute-in-memory (CIM), which refers to a memory used for computation, may be employed.

### SUMMARY

It is an aspect to provide a computing bit cell that supports various types of computations, a device including the same, and a method of operation thereof.

According to an aspect of one or more example embodiments, there is provided a device comprising a computing bit cell; and a control circuit configured to control the computing bit cell. The computing bit cell comprises a memory cell configured to store a coefficient bit; a first transistor that is connected between a first node and a ground node, the first transistor having a gate that is connected to a first line which extends in a first direction and which is configured to receive a voltage based on a first input bit; a second transistor that is connected between a second node and a second line that extends in a second direction that crosses the first direction, the second transistor having a gate that is configured to receive a pre-charge enable signal, the second line being configured to receive a voltage based on a second input bit; and a third transistor that is connected between the first node and the second node, the third transistor having a gate connected to the memory cell.

According to another aspect of one or more example embodiments, there is provided a device comprising a cell array; and a control circuit configured to control the cell array. The cell array comprises a first computing bit cell and a second computing bit cell that are connected to a first line that extends in a first direction, the first computing bit cell and the second computing bit cell being configured to store a first coefficient bit and a second coefficient bit, respectively; a third computing bit cell and a fourth computing bit cell that are connected to a second line that extends in the first direction, the third computing bit cell and the fourth computing bit cell being configured to store a third coefficient bit and a fourth coefficient bit, respectively; a first adder connected to the first computing bit cell; and a first multiplexer configured to selectively provide one of an output of the second computing bit cell and an output of the third computing bit cell to the first adder. The first computing bit cell and the third computing bit cell are connected to a third line that extends in a second direction crossing the first direction, and the second computing bit cell and the fourth computing bit cell are connected to a fourth line that extends in the second direction.

According to yet another aspect of one or more example embodiments, there is provided a device for compute-in-memory (CIM), the device comprising a cell array including a plurality of computing bit cells; and a control circuit configured to selectively operate the cell array in a first mode and a second mode. The cell array comprises a first adder circuit configured to, in the first mode, add together outputs of a first sub-array and a second sub-array, which are adjacent to each other in a first direction and, in the second mode, add together outputs of the first sub-array and a third sub-array, which are adjacent to each other in a second direction that crosses the first direction.

### BRIEF DESCRIPTION OF THE FIGURES

These and/or other aspects will become apparent and more readily appreciated from the following description of example embodiments, taken in conjunction with the accompanying drawings, in which:

FIG. 1 is a block diagram illustrating a device according to an example embodiment;

FIGS. 2A and 2B are diagrams illustrating examples of operations of a cell array according to example embodiments;

FIG. 3 is a circuit diagram illustrating a computing bit cell according to an example embodiment;

FIG. 4 is a circuit diagram illustrating a memory cell according to an example embodiment;

FIGS. 5A and 5B are timing diagrams illustrating operations of a computing bit cell in a cell array which is set in a first mode, according to example embodiments;

FIG. 6 is a table illustrating an operation of a computing bit cell in a cell array which is set in the first mode, according to an example embodiment;

FIGS. 7A and 7B are timing diagrams illustrating operations of a computing bit cell in a cell array which is set in a second mode, according to example embodiments;

FIG. 8 is a table illustrating an operation of a computing bit cell in a cell array which is set in the second mode, according to an example embodiment;

FIG. 9 is a block diagram illustrating a cell array, according to an example embodiment;

FIG. 10 is a block diagram illustrating a cell array, according to an example embodiment;

FIG. 11 is a block diagram illustrating a cell array, according to an example embodiment;

FIG. 12 illustrates examples of a sub-array, according to an example embodiment;

FIGS. 13A and 13B are flowcharts illustrating examples of methods of operating a device including a computing bit cell, according to example embodiments; and

FIG. 14 is a block diagram illustrating a System on Chip (SoC), according to an example embodiment.

### DETAILED DESCRIPTION

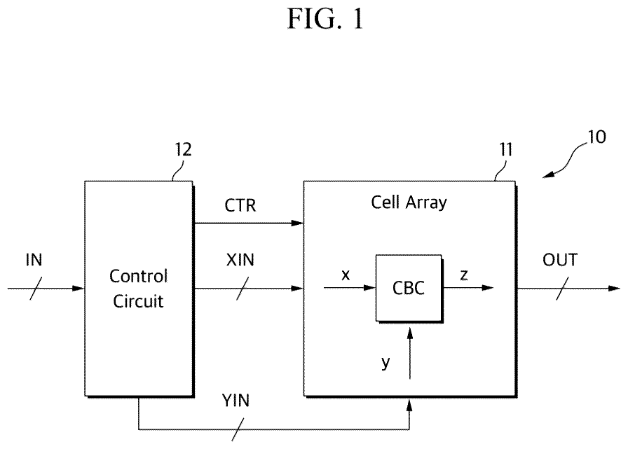

FIG. 1 is a block diagram illustrating a device 10 according to an example embodiment. For example, the block diagram of FIG. 1 shows the device 10 that provides compute-in-memory (CIM) functionality. In some embodiments, the device 10 may be included in an integrated circuit which is fabricated using a semiconductor manufacturing process. As shown in FIG. 1, the device 10 may include a cell array 11 and a control circuit 12.

The cell array 11 may include computing bit cells (CBC). Unlike a structure in which processing elements store data in an external memory, such as random-access memory (RAM), and process the stored data, in-memory computing, or compute-in-memory (CIM) may refer to a structure in which calculation is performed at a memory cell level. Through this calculation at the memory cell level, data transfer between RAM and processing elements may be reduced, thereby allowing for faster data processing. In particular, energy consumed in transferring data between RAM and processing elements may outweigh energy consumed for data processing itself, especially in artificial neural networks, where a large number of parameters are to be processed (e.g., during matrix operations). A large language model (LLM), as an example of the artificial neural networks, may refer to a deep learning model which is trained on an enormous amount of data, and the number of parameters may increase as the large language models continue to evolve.

Applications may include a large number of parameters as well as various types of calculations. For example, the large language model may include transform calculations, and in the transform calculations, an attention mechanism may play a key role. The attention mechanism may include three matrix multiplications, for which CIM may be employed. The three matrix multiplications may include two general matrix multiplications and one transpose matrix multiplication. A buffer for reordering parameters may be used to perform the transpose matrix multiplication within a CIM structure designed for general matrix multiplications. Accordingly, resources for the buffer, and additional time and energy may be required to write and read parameters to and from the buffer. As described hereinafter with reference to the drawings, the device 10 according to some example embodiments may perform general matrix multiplications and transpose matrix multiplications without requiring additional resources, such as the buffer. Accordingly, performance and efficiency of the device 10, a system including the device 10, and an application provided by the system may be enhanced.

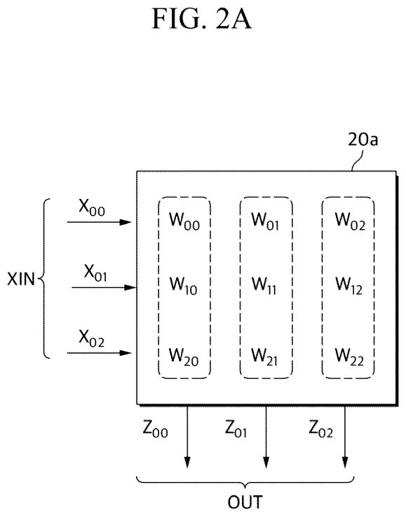

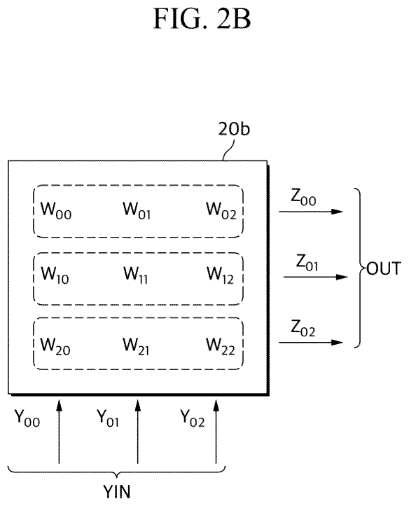

The cell array 11 may be set to a first mode for general matrix multiplications or a second mode for transpose matrix multiplications. That is, the cell array 11 may be operated selectively in the first mode for general matrix multiplications and the second mode for transpose matrix multiplications. In the first mode, the cell array 11 may generate an output OUT by performing calculations based on a first input XIN provided by the control circuit 12 and based on values stored in the cell array 11. In the second mode, the cell array 11 may generate an output OUT by performing calculations based on a second input YIN provided by the control circuit 12 and based on values stored in the cell array 11. A description of examples of operations of the cell array 11 in the first mode and second mode will be provided with reference to FIGS. 2A and 2B.

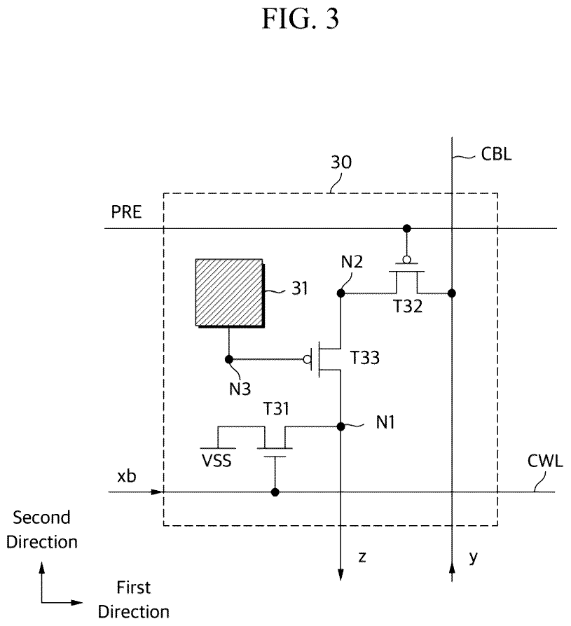

Referring to FIG. 1, the computing bit cell CBC may receive a first input bit x and a second input bit y, and generate an output bit z. In the first mode, the computing bit cell CBC may generate the output bit z by performing a calculation based on bits stored in the computing bit cell CBC (which may be referred to as coefficient bits herein) and the first input bit x. In the second mode, the computing bit cell CBC may generate the output bit z by performing a calculation based on bits stored in the computing bit cell CBC and the second input bit y. An example of the computing bit cell CBC will be described with reference to FIG. 3.

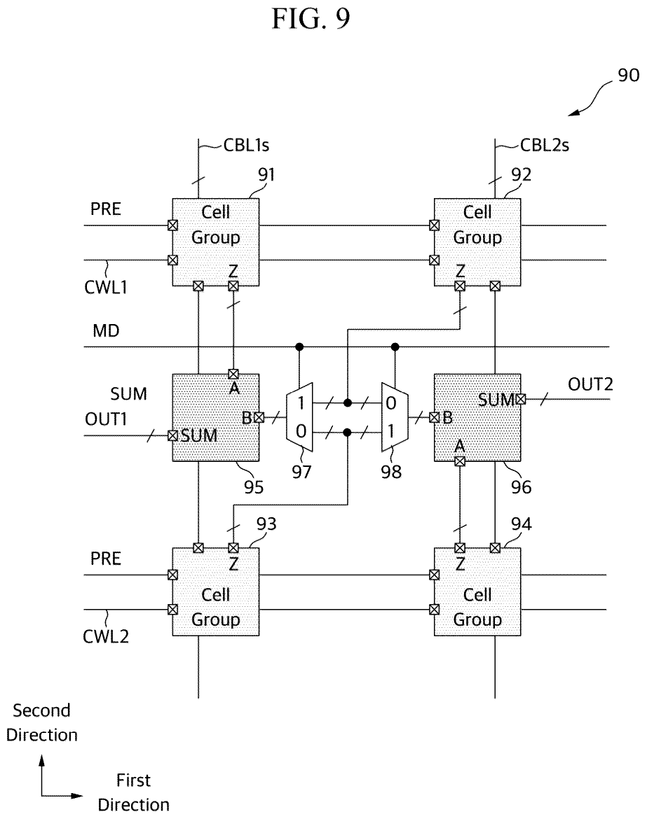

The control circuit 12 may receive an input IN, and provide the first input XIN, the second input YIN, and a control signal CTR to the cell array 11. The control circuit 12 may identify whether the input IN corresponds to general matrix multiplication or transpose matrix multiplication, and set the cell array 11 to the first or second mode based on the result. That is, the control circuit 12 may identify whether the input IN corresponds to general matrix multiplication or transpose matrix multiplication, and selectively operate the cell array 11 in the first mode and the second mode based on whether the input IN corresponds to the general matrix multiplication or the transpose matrix multiplication. For example, when the input IN is identified as the general matrix multiplication, the control circuit 12 may provide the first input XIN, corresponding to values included in the input IN, to the cell array 11. When the input IN is identified as the transpose matrix multiplication, the control circuit 12 may provide the second input YIN, corresponding to values included in the input IN, to the cell array 11. The control circuit 12 may set the mode of the cell array 11 through the control signal CTR, and control operations of the cell array 11. In other words, the control circuit 12 may use the control signal CTR to selectively operate the cell array 11 in the first mode and the second mode. For example, the control signal CTR may include a pre-charge enable signal PRE and a mode signal MD, shown in FIG. 9.

FIGS. 2A and 2B are diagrams illustrating examples of operations of a cell array, according to example embodiments. For example, FIG. 2A illustrates an operation of a cell array 20a which is set in the first mode, and FIG. 2B illustrates an operation of a cell array 20b which is set in the second mode. Although FIGS. 2A and 2B illustrate examples of 3×3 matrix multiplication for illustrative purposes, this is only an example and, in some example embodiments, the cell array may perform matrix multiplications of sizes other than 3×3. In some embodiments, the cell array 20a and the cell array 20b may correspond to the cell array 11 in FIG. 1. Hereinafter, FIGS. 2A and 2B will be described with reference to FIG. 1.

Referring to FIG. 2A, the cell array 20a may perform general matrix multiplication operation shown in Equation 1 below in the first mode.

$$X \times W = Z \qquad [ Equation 1 ]$$

$$( \begin{matrix}{x}_{00} & {x}_{01} & {x}_{02} \\ {x}_{10} & {x}_{11} & {x}_{12} \\ {x}_{20} & {x}_{21} & {x}_{22}\end{matrix} ) \times ( \begin{matrix}{w}_{00} & {w}_{01} & {w}_{02} \\ {w}_{10} & {w}_{11} & {w}_{12} \\ {w}_{20} & {w}_{21} & {w}_{22}\end{matrix} ) = ( \begin{matrix}{z}_{00} & {z}_{01} & {z}_{02} \\ {z}_{10} & {z}_{11} & {z}_{12} \\ {z}_{20} & {z}_{21} & {z}_{22}\end{matrix} )$$

In general matrix multiplication, a calculation between a row of matrix X and a column of matrix W may be carried out. For example, as shown in FIG. 2A, an element z₀₀ of matrix Z may be generated from a first row of matrix X and a first column of matrix W. Similarly, elements z₀₁ and z₀₂ of matrix Z may be generated simultaneously with element z₀₀. The control circuit 12 may provide rows of matrix X to the cell array 20a as the first input XIN sequentially, and the cell array 20a may generate rows of matrix Z as the output OUT sequentially. As shown in FIG. 2A, the first mode may be referred to as horizontal input vertical accumulation (HIVA) herein, since the input is provided in a horizontal direction and accumulate calculation is performed in a vertical direction.

Referring to FIG. 2B, a cell array 20b may perform transpose matrix multiplication operation shown in Equation 2 below in the second mode.

$$Y \times {W}^{T} = Z \qquad [ Equation 2 ]$$

$$( \begin{matrix}{y}_{00} & {y}_{01} & {y}_{02} \\ {y}_{10} & {y}_{11} & {y}_{12} \\ {y}_{20} & {y}_{21} & {y}_{22}\end{matrix} ) \times {( \begin{matrix}{w}_{00} & {w}_{01} & {w}_{02} \\ {w}_{10} & {w}_{11} & {w}_{12} \\ {w}_{20} & {w}_{21} & {w}_{22}\end{matrix} )}^{T} = ( \begin{matrix}{z}_{00} & {z}_{01} & {z}_{02} \\ {z}_{10} & {z}_{11} & {z}_{12} \\ {z}_{20} & {z}_{21} & {z}_{22}\end{matrix} )$$

In transpose matrix multiplication, a calculation between a row of matrix Y and a row of matrix W may be carried out. For example, as shown in FIG. 2B, an element z₀₀ of matrix Z may be generated from a first row of matrix Y and a first row of matrix W. The control circuit 12 may provide rows of matrix Y to the cell array 20b as the second input YIN sequentially, and the cell array 20b may generate rows of matrix Z as the output OUT sequentially. As shown in FIG. 2B, the second mode may be referred to as vertical input horizontal accumulation (VIHA) herein, since the input is provided in a vertical direction and accumulate calculation is performed in a horizontal direction. As described with reference to FIGS. 2A and 2B, according to an example embodiment, elements of matrix W stored in the cell array may be maintained in general matrix multiplication and transpose matrix multiplication, and resources, such as a buffer, and operations for rearranging the elements of matrix W may be omitted.

FIG. 3 is a circuit diagram illustrating a computing bit cell 30, according to an example embodiment. As described above with reference to FIG. 1, in an example embodiment, the computing bit cell 30 may correspond to the computing bit cell (CBC) included in the cell array 11 which may be selectively operated in the first mode and second mode. As shown in FIG. 3, the computing bit cell 30 may include a first transistor T31, a second transistor T32 and a third transistor T33 and a memory cell 31. The first transistor T31 may be an n-channel field effect transistor (NFET), and each of the second and third transistors T32 and T33 may be a p-channel field effect transistor (PFET). Hereinafter, FIG. 3 will be described with reference to FIG. 1.

Referring to FIG. 3, the computing bit cell 30 may be connected to a computing word line CWL that extends in a first direction and to a computing bit line CBL that extends in a second direction. The first and second directions may intersect with each other, and in some embodiments, the first and second directions may intersect perpendicularly. In some embodiments, each of the computing word line CWL and computing bit line CBL may correspond to a pattern formed on a wiring layer of an integrated circuit. In some embodiments, a computing bit cell that is adjacent to the computing bit cell 30 in the first direction may be connected to the computing word line CWL, and a computing bit cell that is adjacent to the computing bit cell 30 in the second direction may be connected to the computing bit line CBL.

As shown in FIG. 3, the computing bit cell 30 may receive an inverted bit xb of the first input bit x through the computing word line CWL, may receive the second input bit y through the computing bit line CBL, and may generate the output bit z. The computing bit cell 30 may receive the pre-charge enable signal PRE. Each of the first input bit x, second input bit y, and output bit z may correspond to a bit of a matrix element. The pre-charge enable signal PRE may be an active low signal. An active high signal may be at a logic high level when activated and at a logic low level when deactivated. An active low signal may be at a logic low level when activated and at a logic high level when deactivated. Herein, the logic high level may be represented by the number 1, and the logic low level may be represented by the number 0. It is assumed that the logic high level corresponds to a voltage close to a positive supply voltage VDD and the logic low level corresponds to a voltage close to a negative supply voltage VSS or ground potential.

The first transistor T31 may be connected between a node to which the negative supply voltage VSS is received and a first node N1, and may have a gate connected to the computing word line CWL. Herein, an element being connected to a node to which the negative supply voltage VSS or the positive supply voltage VDD is received may simply be referred to as an element being connected to the negative supply voltage VSS or to the positive supply voltage VDD. The node to which the negative supply voltage VSS or a ground potential is connected may be referred to as a ground node. The second transistor T32 may be connected between the computing bit line CBL and a second node N2, and may have a gate that receives the pre-charge enable signal PRE. The third transistor T33 may be connected between the first node N1 and the second node N2, and may have a gate connected to the memory cell 31 through a third node N3.

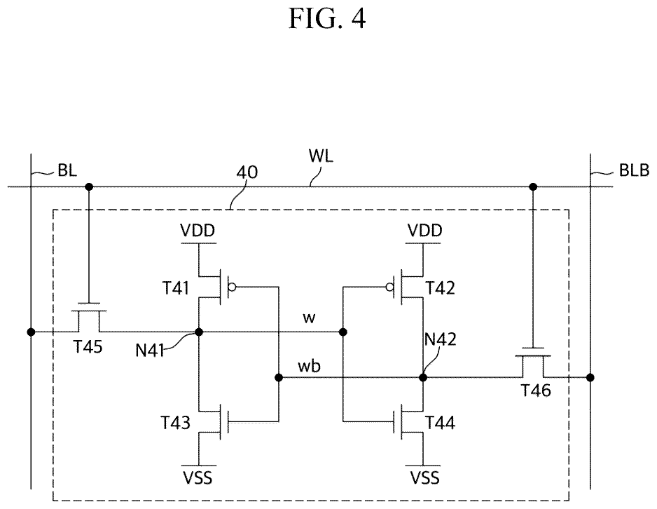

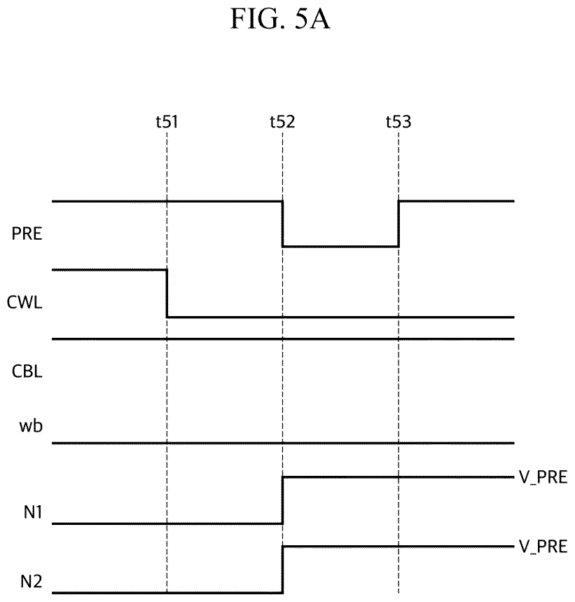

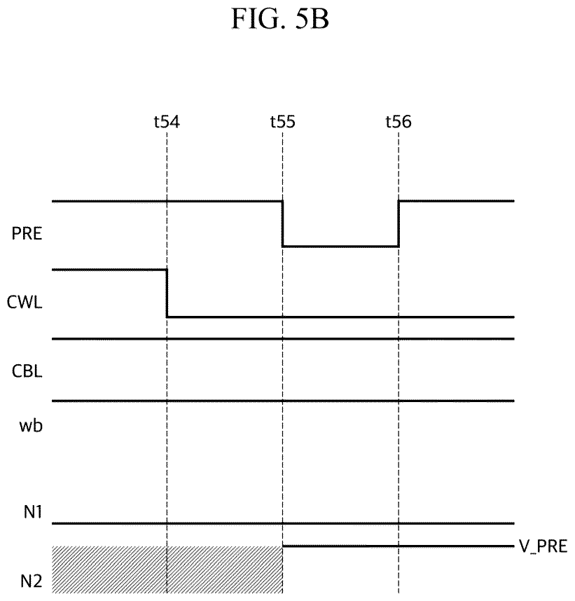

The memory cell 31 may store one bit. For example, the memory cell 31 may store a coefficient bit. The memory cell 31 may have any structure for storing the coefficient bit. A description of an example of the memory cell 31 will be provided with reference to FIG. 4. As will be described with reference to FIG. 4, when the memory cell 31 includes six transistors, the computing bit cell 30 may include a total of nine transistors. In some example embodiments, the gate of the third transistor T33 may be connected to a terminal for outputting an inverted bit of the bit stored in the memory cell 31. Accordingly, the gate of the third transistor T33 may receive a signal corresponding to the inverted bit of the coefficient bit. Descriptions of examples of operations of the computing bit cell 30 will be provided hereinafter with reference to FIGS. 5A and 5B.

FIG. 4 is a circuit diagram illustrating a memory cell 40, according to an example embodiment. In an example embodiment, as described above, the memory cell 40 may be an example of the memory cell 31 described above with respect to FIG. 3. In an example embodiment, the circuit diagram of FIG. 4 shows the memory cell 40, which is a static random-access memory (SRAM) cell, as an example of a memory cell. However, the memory cell 31 of FIG. 3 is not limited to the memory cell 40 of FIG. 4.

As shown in FIG. 4, the memory cell 40 may include a first transistor T41, a second transistor T2, a third transistor T3, a fourth transistor T4, a fifth transistor T5, and a sixth transistor T46. The first and second transistors T41 and T42 may be PFETs, and the third to sixth transistors T43 to T46 may be NFETs.

The first to fourth transistors T41 to T44 may correspond to a pair of inverters cross-coupled between a first node N41 and a second node N42. The first and second transistors T41 and T42 may be referred to as pull-up transistors, and the third and fourth transistors T43 and T44 may be referred to as pull-down transistors. The fifth transistor T45 may be connected between a bit line BL and the first node, and may include a gate connected to a word line WL. The sixth transistor T46 may be connected between a complementary bit line BLB and the second node, and may include a gate connected the word line WL. The fifth and sixth transistors T45 and T46 may be referred to as pass transistors. When the word line WL is activated, the fifth transistor T45 may electrically connect the bit line BL and the first node N41, and the sixth transistor T46 may electrically connect the complementary bit line BLB and the second node N42.

The memory cell 40 may store a coefficient bit w. The first node N41 may have a voltage corresponding to the coefficient bit w and the second node N42 may have a voltage corresponding to an inverted bit wb of the coefficient bit w. As described above with reference to FIG. 3, the third transistor T33 of the computing bit cell 30 may include a gate which receives an inverted bit of a coefficient bit, and accordingly, the gate of the third transistor T33 may be connected to the second node N42 of FIG. 4. Herein, the second node N42 may be referred to as a first latch node, and the first node N41 may be referred to as a second latch node.

FIGS. 5A and 5B are timing diagrams illustrating operations of a computing bit cell in a cell array which is set in the first mode, according to example embodiments. For example, FIG. 5A shows an initialization process of a computing bit cell when the coefficient bit w stored in a memory cell included in the computing bit cell is ‘1’, and FIG. 5B shows an initialization process of a computing bit cell when the coefficient bit w included in a memory cell included in the computing bit cell is ‘0’. In some example embodiments, the operations of FIGS. 5A and 5B may be performed by the computing bit cell 30 of FIG. 3. As will be described hereinafter, the second node N2 may be pre-charged to a pre-charge voltage V_PRE, which is close to the positive supply voltage VDD, regardless of the coefficient bit w, due to the initialization process in the first mode. Hereinafter, FIGS. 5A and 5B will be described with reference to FIG. 3, and a redundant description will be omitted for conciseness.

Referring to FIG. 5A, the pre-charge enable signal PRE may be deactivated before time t51, which means being at a logic high level, the computing word line CWL and computing bit line CBL may also be at a logic high level, and an inverted coefficient bit wb may be at a logic low level. As a result, the first and third transistors T31 and T33 may be turned on, and the second transistor T32 may be turned off. The first node N1 may be pulled down to the negative supply voltage VSS by the first transistor T31, and the second node N2 may also be pulled down by the third transistor T33.

At time t51, the computing word line CWL may transition to a logic low level, and the first transistor T31 may be turned on as a result. The first and second nodes N1 and N2 may be floated, and the negative supply voltage VSS may be maintained as a result. At time t52, the pre-charge enable signal PRE may be activated, which means the pre-charge enable signal PRE may transition to a logic low level, and the second transistor T32 may be turned on as a result. The second node N2 may be pulled up as a result of a pulled-up computing bit line CBL, and the first node N1 may also be pulled up through the third transistor T33. At time t53, the pre-charge enable signal PRE may be deactivated again, which means the pre-charge enable signal PRE may transition to a logic high level, and the second transistor T32 may be turned off as a result. The first and second nodes N1 and N2 may be floated again, and maintain the pull-up state. That is, as shown in FIG. 5A, the second node N2 may be pre-charged to the pre-charge voltage V_PRE, which is close to the positive supply voltage VDD.

Referring to FIG. 5B, the pre-charge enable signal PRE may be deactivated before time t54, the computing word line CWL and computing bit line CBL may be at a logic high level, and the inverted coefficient bit wb may also be at a logic high level. As a result, the first transistor T31 may be turned on, and the second and third transistors T32 and T33 may be turned off. The first node N1 may be pulled down to the negative supply voltage VSS by the first transistor T31, and the second node N2 may be floated.

At time t54, the computing word line CWL may transition to a logic low level, and the first transistor T31 may be turned off as a result. The first node N1 may be floated, and may maintain the negative supply voltage VSS as a result. At time t55, the pre-charge enable signal PRE may be activated, and the second transistor T32 may be turned on as a result. The second node N2 may be pulled up as a result of the pulled-up computing bit line CBL. At time t56, the pre-charge enable signal PRE may be deactivated again, and the second transistor T32 may be turned off as a result. The second node N2 may be floated again, and may maintain the pull-up state. That is, as shown in FIG. 5B, the second node N2 may be pre-charged to the pre-charge voltage V_PRE, which is close to the positive supply voltage VDD. It is noted that FIG. 5B is described with reference to times t54, t55, and t56 and FIG. 5A is described with reference to times t51, t52, and t53. However, the use of these times is not necessarily intended to imply any specific temporal relationship between the times in FIG. 5A and the times in FIG. 5B, but rather only to distinguish the times in FIG. 5B from the times in FIG. 5A for descriptive purposes. For example, in some example embodiments, times t54, t55, and t56 may come after times t51, t52, and t53. In some example embodiments, times t51, t52, and t53 may come after times t54, t55, and t56.

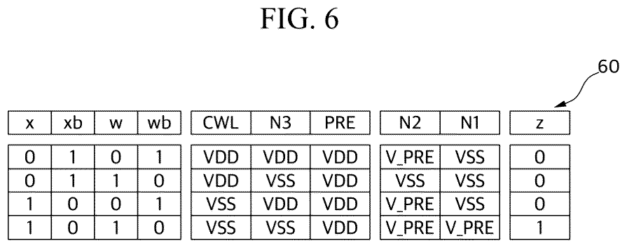

FIG. 6 is a table 60 illustrating an operation of a computing bit cell in a cell array which is set in the first mode, according to example embodiments. For example, the table 60 of FIG. 6 shows voltages and values corresponding to combinations of the first input bit x and coefficient bit w in an initialized computing bit cell based on the coefficient bit w, as described above with reference to FIGS. 5A and 5B. As described above with reference to FIGS. 5A and 5B, the second node N2 may be pre-charged to the pre-charge voltage V_PRE, which is close to the positive supply voltage VDD, in the computing bit cell 30 which is initialized in the first mode. Hereinafter, FIG. 6 will be described with reference to FIG. 3.

A voltage corresponding to the inverted bit xb of the first input bit x may be applied to the computing word line CWL. For example, the control circuit 12 of FIG. 1 may apply a voltage corresponding to the inverted bit xb of the first input bit x in the first mode to the computing word line CWL. A voltage corresponding to the inverted coefficient bit wb may be applied to the third node N3. The pre-charge enable signal PRE may be deactivated by the control circuit 12, and the pre-charge enable signal PRE may correspond to the positive supply voltage VDD. The first and second nodes N1 and N2 may have voltages determined based on a voltage of the computing word line CWL and a voltage of the third node N3.

As shown in FIG. 6, the voltage of the first node N1 may be the pre-charge voltage V_PRE when the first input bit x is ‘1’ and coefficient bit w is ‘1’, and the voltage of the first node N1 may be the negative supply voltage VSS otherwise. The output bit z may correspond to the voltage of the first node N1, which may result in having a value corresponding to a product of the first input bit x and the coefficient bit w.

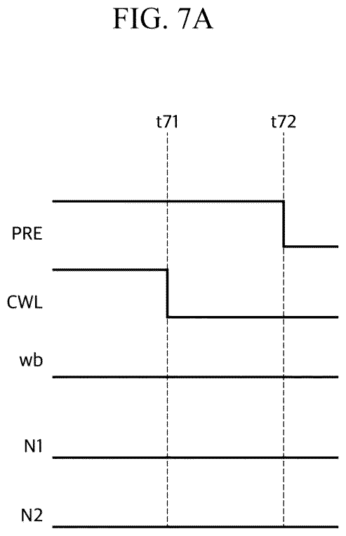

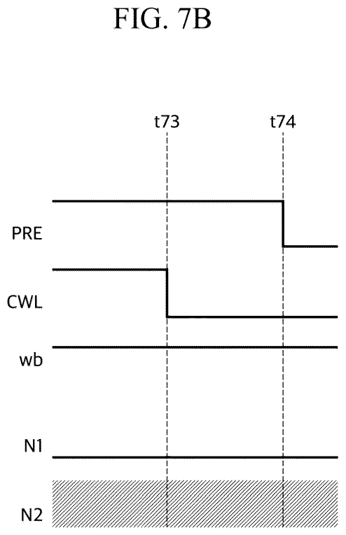

FIGS. 7A and 7B are timing diagrams illustrating operations of a computing bit cell in a cell array which is set in the second mode, according to example embodiments. For example, FIG. 7A shows an initialization process of a computing bit cell when the coefficient bit w stored in a memory cell which is included in the computing bit cell is ‘1’, and FIG. 7B shows an initialization operation of a computing bit cell when the coefficient bit w included in a memory cell which is included in the computing bit cell is ‘0’. In some example embodiments, the operations of FIGS. 7A and 7B may be performed by the computing bit cell 30 of FIG. 3. As will be described hereinafter, the first node N1 may be pulled down to the negative supply voltage VSS by an initialization process in the second mode, regardless of the coefficient bit w. Hereinafter, FIGS. 7A and 7B will be described with reference to FIG. 3, and a redundant description will be omitted for conciseness.

Referring to FIG. 7A, the pre-charge enable signal PRE may be deactivated, which means being at a logic high level, before time t71, the computing word line CWL may also be at a logic high level, and the inverted coefficient bit wb may be at a logic low level. As a result, the first and third transistors T31 and T33 may be turned on, and the second transistor T32 may be turned off. The first node N1 may be pulled down to the negative supply voltage VSS by the first transistor T31, and the second node N2 may also be pulled down by the third transistor T33.

At time t71, the computing word line CWL may transition to a logic low level, and the first transistor T31 may be turned off as a result. The first and second nodes N1 and N2 may be floated, and the negative supply voltage VSS may be maintained as a result. At time t72, the pre-charge enable signal PRE may be activated, which means the pre-charge enable signal PRE may transition to a logic low level, and the second transistor T32 may be turned on as a result. In the second mode, a voltage corresponding to the second input bit y may be applied to the computing bit line CBL, and voltages of the first and second nodes N1 and N2 may be determined based on the voltage of the computing bit line CBL after time t72.

Referring to FIG. 7B, before time t73, the pre-charge enable signal PRE may be deactivated, the computing word line CWL and computing bit line CBL may be at a logic high level, and the inverted coefficient bit wb may also be at a logic high level. As a result, the first transistor T31 may be turned on, and the second and third transistors T32 and T33 may be turned off. The first node N1 may be pulled down to the negative supply voltage VSS by the first transistor T31, and the second node N2 may be floated.

At time t73, the computing word line CWL may transition to a logic low level, and the first transistor T31 may be turned off as a result. The first node N1 may be floated, and the negative supply voltage may be maintained as a result. At time t74, the pre-charge enable signal PRE may be activated, and the second transistor T32 may be turned on as a result. In the second mode, a voltage corresponding to the second input bit y may be applied to the computing bit line CBL, and voltages of the first and second nodes N1 and N2 may be determined based on the voltage of the computing bit line CBL after time t74. It is noted that FIG. 7B is described with reference to times t73 and t74 and FIG. 7A is described with reference to times t71 and t72. However, the use of these times is not necessarily intended to imply any specific temporal relationship between the times in FIG. 7A and the times in FIG. 7B, but rather only to distinguish the times in FIG. 7B from the times in FIG. 7A for descriptive purposes. For example, in some example embodiments, times t73 and t74 may come after times t71 and t72. In some example embodiments, times t71 and t72 may come after times t73 and t74.

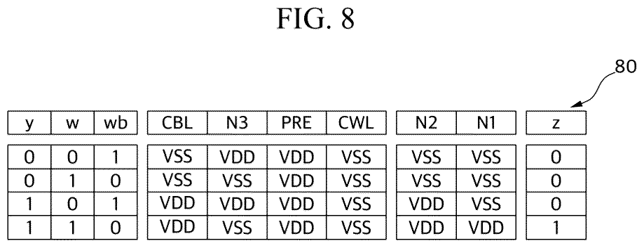

FIG. 8 is a table 80 illustrating an operation of a computing bit cell in a cell array which is set in the second mode, according to example embodiments. For example, a table 80 of FIG. 8 shows voltages and values corresponding to combinations of the first input bit x and coefficient bit w in an initialized computing bit cell based on the coefficient bit w, as described with reference to FIGS. 7A and 7B. As described above with reference to FIGS. 7A and 7B, the first node N1 may be pulled down to the negative supply voltage VSS in the computing bit cell 30 which is initialized in the second mode. Hereinafter, FIG. 8 will be described with reference to FIG. 3.

A voltage corresponding to the second input bit y may be applied to the computing bit line CBL. For example, the control circuit 12 of FIG. 1 may apply a voltage corresponding to the second input bit y to the computing bit line CBL in the second mode. A voltage corresponding to the inverted coefficient bit wb may be applied to the third node N3. The pre-charge enable signal PRE may be deactivated by the control circuit 12, and the pre-charge enable signal PRE may correspond to the positive supply voltage VDD. The negative supply voltage VSS may be applied to the computing word line CWL by the control circuit 12. The first and second nodes N1 and N2 may have voltages determined based on the voltage of the computing bit line CBL and the voltage of the third node N3.

As shown in FIG. 8, the voltage of the first node N1 may be the positive supply voltage VDD when the second input bit y is ‘1’ and coefficient bit w is ‘1’, and the voltage of the first node N1 may be the negative supply voltage VSS otherwise. The output bit z may correspond to the voltage of the first node N1, which may result in having a value corresponding to a product of the first input bit x and the coefficient bit w.

FIG. 9 is a block diagram illustrating a cell array, according to an example embodiment. In an example embodiment, the cell array illustrated in FIG. 9 may correspond to the cell array 11 of FIG. 1. In an example embodiment, the block diagram of FIG. 9 may show a sub-array 90 included in the cell array. As shown in FIG. 9, the sub-array 90 may include a first cell group 91, a second cell group 92, a third cell group 93, and a fourth cell group 94, a first adder 95, a second adder 96, a first multiplexer 97, and a second multiplexer 98. In some embodiments, each of the first multiplexer 97 and second multiplexer 98 may be replaced with two switches which are controlled by two control signals indicating a mode. Herein, the sub-array of FIG. 9 may be referred to as a first stage sub-array.

Each of the first to fourth cell groups 91 to 94 may include N (a whole number greater than 1) number of computing bit cells. The N number of computing bit cells in one cell group may be connected to the computing word line CWL that extends in the first direction, or may be connected to each of N number of computing bit lines CBLs that extend in the second direction. The N number of computing bit cells may store a coefficient of N-bit. Each of the first to fourth cell groups 91 to 94 may receive the pre-charge enable signal PRE. As described above with reference to FIGS. 1 to 7A and 7B, each of the first to fourth cell groups 91 to 94 may generate the output z by performing product of the first input provided through the computing word line CWL and the stored coefficient in the first mode, and may generate the output z by performing product of the second input provided through the N number of computing bit lines CBLs and the stored coefficient in the second mode.

Referring to FIG. 9, the first and second cell groups 91 and 92, which are adjacent to each other in the first direction, may be connected to a first computing word line CWL1, and the third and fourth cell groups 93 and 94, which are adjacent to each other in the first direction, may be connected to a second computing word line CWL2. The first and third cell groups 91 and 93, which are adjacent to each other in the second direction, may be connected to N number of first computing bit lines CBL1s, and the second and fourth cell groups 92 and 94, which are adjacent to each other in the second direction, may be connected to N number of second computing bit lines CBL2s.

Each of the first and second adders 95 and 96 may generate an output SUM by summing two N-bit inputs A and B. As shown in FIG. 9, the input A of the first adder 95 may be connected to an output of the first cell group 91, and the input B of the first adder 95 may be connected to an output of the first multiplexer 97. The first multiplexer 97 may select one of an output of the second cell group 92 and an output of the third cell group 93 based on a mode signal MD, and may provide the selected output to the first adder 95. For example, the first multiplexer 97 may select the output of the third cell group 93 when the mode signal MD has a value of ‘0’, indicating the first mode, and may select the output of the second cell group 92 when the mode signal MD has a value of ‘1’, indicating the second mode. Accordingly, the first adder 95 may generate a first output OUT 1 by summing outputs of the first and third cell groups 91 and 93, in the first mode, and by summing outputs of the first and second cell groups 91 and 92, in the second mode, based on the mode signal MD.

The input A of the second adder 96 may be connected to an output of the fourth cell group 94, and the input B of the second adder 96 may be connected to an output of the second multiplexer 98. The second multiplexer 98 may select one of an output of the second cell group 92 and an output of the third cell group 93 based on the mode signal MD, and may provide the selected output to the second adder 96. For example, the second multiplexer 98 may select the output of the second cell group 92 when the mode signal MD has a value of ‘0’, indicating the first mode, and may select the output of the third cell group 93 when the mode signal MD has a value of ‘1’, indicating the second mode. Accordingly, the second adder 96 may generate a second output OUT2 by summing outputs of the second and fourth cell groups 92 and 94, in the first mode, and by summing outputs of the third and fourth cell groups 93 and 94, in the second mode, based on the mode signal MD.

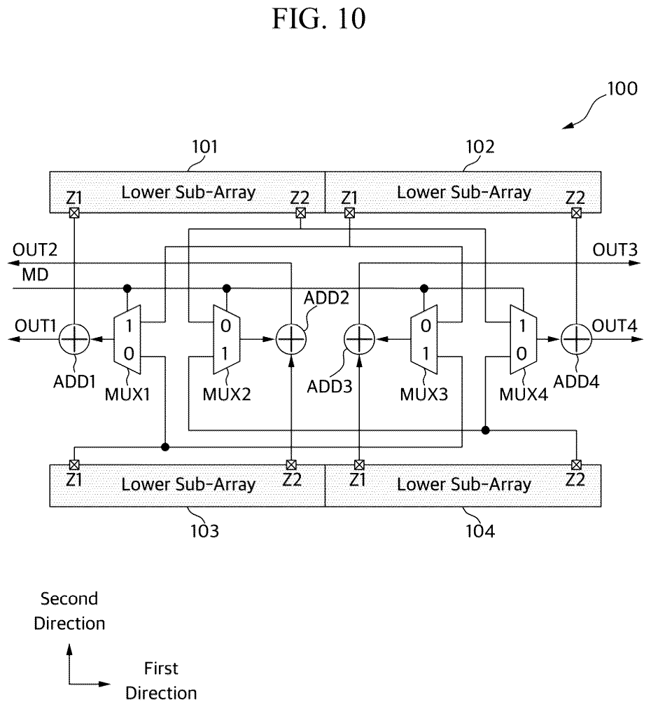

FIG. 10 is a block diagram illustrating a cell array, according to an example embodiment. In an example embodiment, the cell array illustrated in FIG. 10 may correspond to the cell array 11 of FIG. 1. In an example embodiment, the block diagram of FIG. 10 shows a sub-array 100 including the sub-array 90 of FIG. 9. As shown in FIG. 10, the sub-array 100 may include a first lower sub-array 101, a second lower sub-array 102, a third lower sub-array 103, and a fourth lower sub-array, a first adder ADD1, a second adder ADD2, a third adder ADD3, and a fourth adder ADD4, and a first multiplexer MUX1, a second multiplexer MUX2, a third multiplexer MUX3, and a fourth multiplexer MUX4. In some embodiments, each of the first to fourth multiplexers MUX1 to MUX4 may be replaced with two switches which are controlled by two control signals indicating a mode. Herein, the sub-array 100 of FIG. 10 may be referred to as a second stage sub-array.

In some embodiments, each of the first to fourth lower sub-arrays 101 to 104 may correspond to the sub-array 90 of FIG. 9. As described above with reference to FIG. 9, each of the first to fourth lower sub-arrays 101 to 104 may have two outputs Z1 and Z2. Referring to FIG. 10, the first and second lower sub-arrays 101 and 102 may be adjacent to each other in the first direction, and the third and fourth lower sub-arrays 103 and 104 may be adjacent to each other in the first direction. The first and third lower sub-arrays 101 and 103 may be adjacent to each other in the second direction, and the second and fourth lower sub-arrays 102 and 104 may be adjacent to each other in the second direction.

The first adder ADD1 may generate the first output OUT1 by summing the output Z1 of the first lower sub-array 101 and an output of the first multiplexer MUX1. The first multiplexer MUX1 may select and provide the output Z1 of the third lower sub-array 103 to the first adder ADD1 when the mode signal MD indicates the first mode, and may select and provide the output Z1 of the second lower sub-array 102 to the first adder ADD1 when the mode signal MD indicates the second mode.

The second adder ADD2 may generate the second output OUT2 by summing the output Z2 of the third lower sub-array 103 and an output of the second multiplexer MUX2. The second multiplexer MUX2 may select and provide the output Z2 of the first lower sub-array 101 to the second adder ADD2 when the mode signal MD indicates the first mode, and may select and provide the output Z2 of the fourth lower sub-array 104 to the second adder ADD2 when the mode signal MD indicates the second mode.

A third adder ADD3 may generate a third output OUT3 by summing the output Z1 of the fourth lower sub-array 104 and an output of the third multiplexer MUX3. The third multiplexer MUX3 may select and provide the output Z1 of the second lower sub-array 102 to the third adder ADD3 when the mode signal MD indicates the first mode, and may select and provide the output Z1 of the third lower sub-array 103 to the third adder ADD3 when the mode signal MD indicates the second mode.

A fourth adder ADD4 may generate a fourth output OUT4 by summing the output Z2 of the second lower sub-array 102 and an output of the fourth multiplexer MUX4. The fourth multiplexer MUX4 may select and provide the output Z2 of the fourth lower sub-array 104 to the fourth adder ADD4 when the mode signal MD indicates the first mode, and may select and provide the output Z2 of the first lower sub-array 101 to the fourth multiplexer MUX4 when the mode signal MD indicates the second mode.

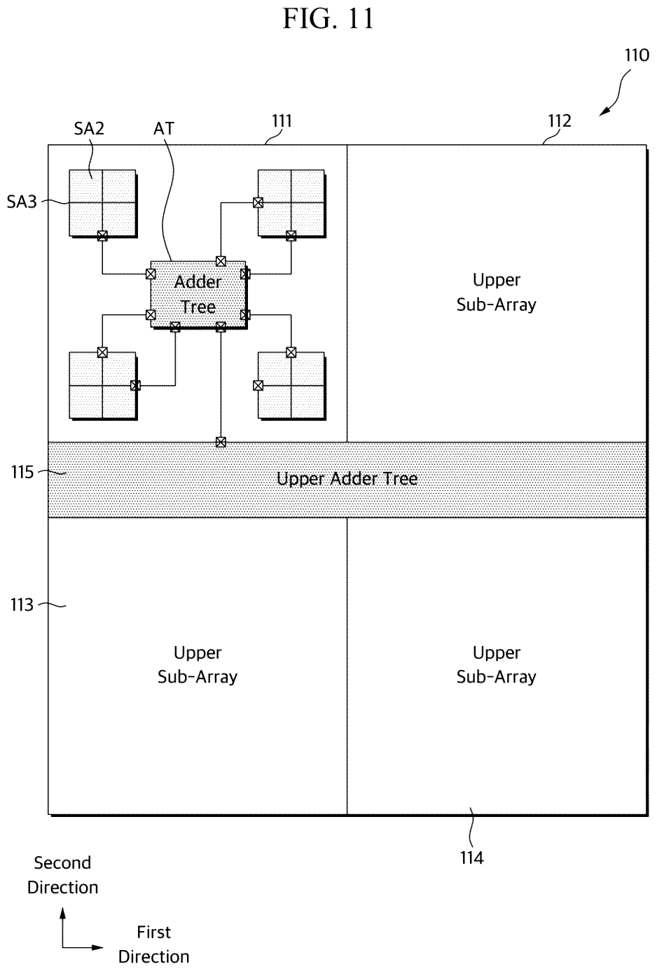

FIG. 11 is a block diagram illustrating a cell array 110, according to an example embodiment. In an example embodiment, the cell array illustrated in FIG. 11 may correspond to the cell array 11 of FIG. 1. In an example embodiment, the block diagram of FIG. 11 shows the cell array 110 including the sub-array 100 of FIG. 10. As shown in FIG. 11, the cell array 110 may include a first upper sub-array 111, a second upper sub-array 112, a third upper sub-array 113, and a fourth upper sub-array 114, and an upper adder tree 115. The first to fourth upper sub-arrays 111 to 114 may have the same structure. Herein, each of the first to fourth upper sub-arrays 111 to 114 may be referred to as a fourth stage sub-array.

Referring to FIG. 11, the first upper sub-array 111 may include four third stage sub-arrays and one adder tree AT. A third stage sub-array SA3 may include four second stage sub-arrays, and a second stage sub-array SA2 may correspond to the sub-array 100 of FIG. 100. The four third stage sub-arrays and one adder tree AT in the first upper sub-array 111 may be connected to each other similarly to the description of the sub-array 100 described above with reference to FIG. 10. The first to fourth upper sub-arrays 111 to 114 and the upper adder tree 115 in the cell array 110 may also be connected to each other similarly to the description of the sub-array 100 described above with reference to FIG. 10. Accordingly, the lower sub-arrays may be connected in an H-tree structure to form an upper sub-array.

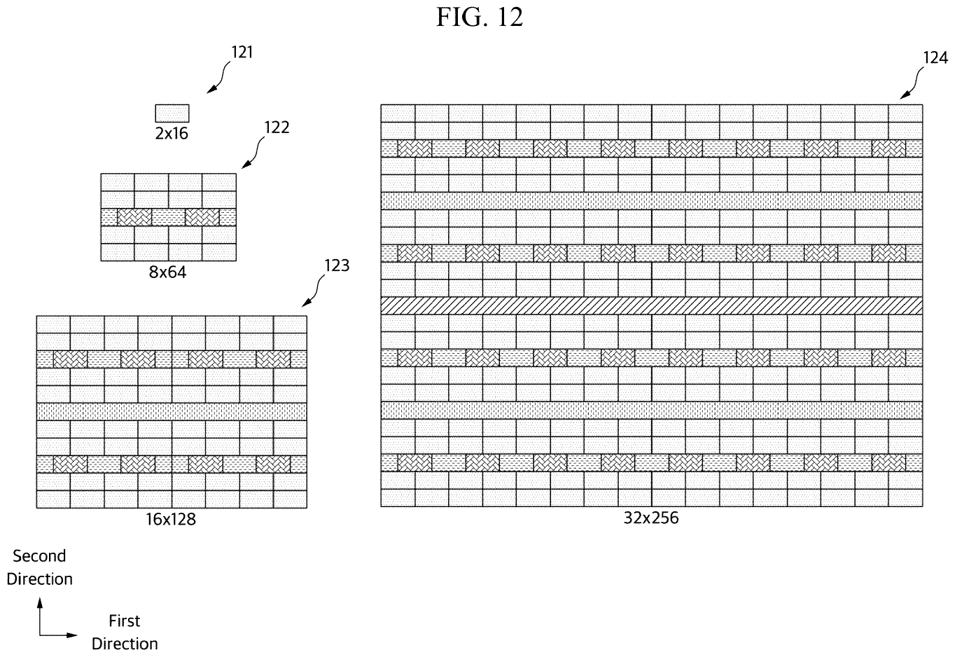

FIG. 12 illustrates examples of a sub-array, according to an example embodiment. For example, FIG. 12 illustrates examples of a sub-array when the N of the sub-array 90 of FIG. 9 is ‘8’, which means, when a coefficient stored in the computing bit cell is 8-bit. As described above with reference to FIG. 11, the sub-arrays may be connected in an H-tree structure.

A first sub-array 121 may have a structure similar to that of the sub-array 90 in FIG. 9, and may include 2×16 computing bit cells. A second sub-array 122 may include 16 first sub-arrays, and may include 8×64 computing bit cells accordingly. A third sub-array 123 may include four second sub-arrays, and may include 16×128 computing bit cells accordingly. A fourth sub-array 124 may include four third sub-arrays, and may include 32×256 computing bit cells accordingly.

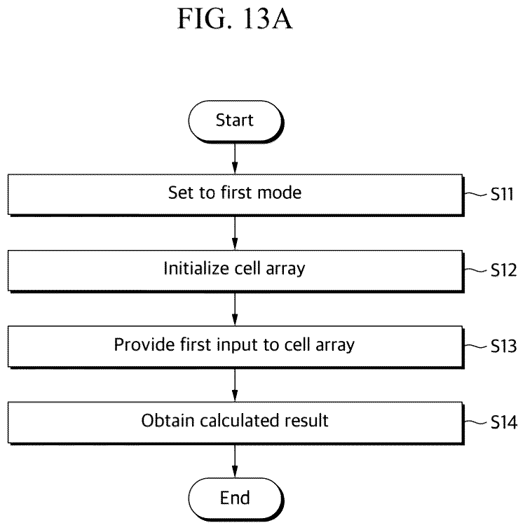

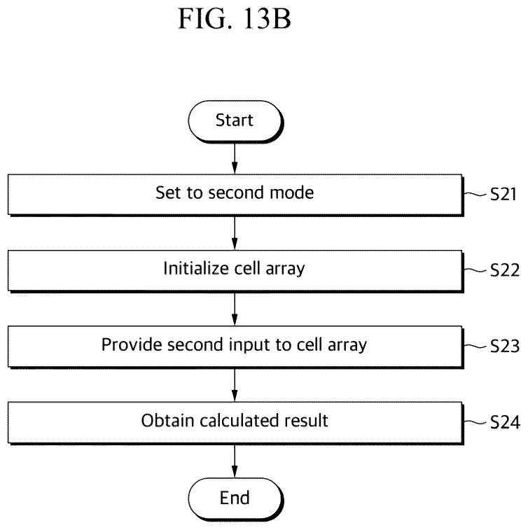

FIGS. 13A and 13B are flowcharts illustrating examples of methods of operating the device including a computing bit cell, according to example embodiments. For example, the flowchart of FIG. 13A illustrates a method of operating the device in the first mode, and the flowchart of FIG. 13B illustrates a method of operating the device in the second mode. In some embodiments, the methods of FIGS. 13A and 13B may be performed by the device 10 of FIG. 1. Hereinafter, FIGS. 13A and 13B will be described with reference to FIG. 1, and a redundant description will be omitted for conciseness.

Referring to FIG. 13A, the method of operating the device 10 may include operations S11 to S14. In operation S11, the device 10 may be set to the first mode. As described above with reference to the drawings, the device 10 in the first mode may perform general matrix multiplication operations. Based on the input IN, the control circuit 12 may identify that general matrix multiplication is to be performed, and may set the cell array 11 to the first mode accordingly. In some example embodiments, the control circuit 12 may generate and provide the mode signal MD indicating the first mode to the cell array 11.

In operation S12, the cell array 11 may be initialized. For example, as described above with reference to FIGS. 5A and 5B, the control circuit 12 may initialize computing bit cells included in the cell array 11 through the computing word line CWL, computing bit line CBL, and pre-charge enable signal PRE. As a result, the second node N2 of the computing bit cell may be pre-charged to the pre-charge voltage V_PRE.

In operation S13, the first input XIN may be provided to the cell array 11. For example, the control circuit 12 may identify elements of a matrix from the input IN, and may provide the first input XIN corresponding to inverted bits of the elements of the matrix to the cell array 11 through the computing word lines.

In operation S14, a calculated result of the operation may be obtained. For example, the cell array 11 may perform multiplication operations between the first input XIN provided in operation S13 and coefficients stored in the cell array 11, and may generate an output OUT by summing the results of the multiplication operations. The output OUT generated in the first mode may correspond to a result of the general matrix multiplication operation.

Referring to FIG. 13B, the method of operating the device 10 may include operations S21 to S24. In operation S21, the device 10 may be set to the second mode. As described above with reference to the drawings, the device 10 in the second mode may perform transpose matrix multiplication operations. Based on the input IN, the control circuit 12 may identify that transpose matrix multiplication is to be performed, and may set the cell array 11 to the second mode accordingly. In some embodiments, the control circuit 12 may generate and provide the mode signal MD indicating the second mode to the cell array 11.

In operation S22, the cell array 11 may be initialized. For example, as described above with reference to FIGS. 7A and 7B, the control circuit 12 may initialize computing bit cells included in the cell array 11 through the computing word line CWL and pre-charge enable signal PRE. As a result, the first node N1 of the computing bit cell may be floated while being pulled down to the negative supply voltage VSS.

In operation S23, the second input YIN may be provided to the cell array 11. For example, the control circuit 12 may identify elements of a matrix from the input IN, and may provide the second input YIN corresponding to bits of the elements of the matrix to the cell array 11 through the computing bit lines.

In operation S24, a calculated result of the operation may be obtained. For example, the cell array 11 may perform multiplication operations between the second input YIN provided in operation S23 and coefficients stored in the cell array 11, and may generate an output OUT by summing the results of the multiplication operations. The output OUT generated in the second mode may correspond to a result of the transpose matrix multiplication operation.

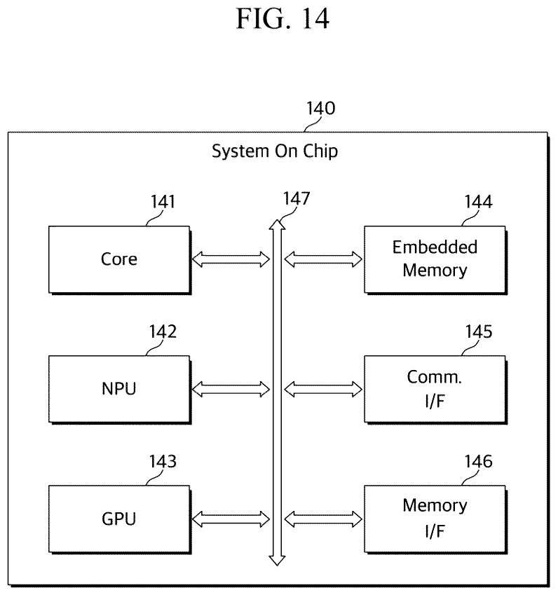

FIG. 14 is a block diagram illustrating a System on Chip (SoC) 140, according to an example embodiment. The System on Chip 140 may refer to a computing system or an integrated circuit in which components of other electronic system are integrated. As an example of the System on Chip 140, an application processor (AP) may include a processor and other components for different functionalities. As shown in FIG. 14, the System on Chip 140 may include a core 141, a neural processing unit (NPU) 142, a graphic processing unit (GPU) 143, an embedded memory 144, a communication interface 145, and a memory interface 146. Elements of the System on Chip 140 may communicate with each other through a bus 147.

The core 141 may process instructions and control operations of the elements included in the System on Chip 140. For example, the core 141 may run an operating system by executing a series of instructions, and run applications on the operating system. The NPU 142 may perform computations for artificial neural networks. The GPU 143 may generate data for images output through a display device, from image data provided by the embedded memory 144 or the memory interface 146, or may encode image data. In some embodiments, the NPU 142 and/or GPU 143 may include computing bit cells described above with reference to FIG. 1 to FIGS. 13A and 13B, thereby achieving enhanced performance, efficiency, and scalability. The embedded memory 144 may store data for the operation of core 141, NPU 142, and GPU 143. The communication interface 145 may provide a communication network or an interface for one-to-one communication. The memory interface 146 may provide an interface to external memory for the System on Chip 140, such as dynamic random-access memory (DRAM) and flash memory.

Various example embodiments have been described with respect to the drawings. While the example embodiments have been described using specific terms, it shall be understood that the terms used herein are only for the purpose of describing the technical spirit of the present disclosure and not for limiting the scope of the present disclosure. Therefore, those skilled in the art will appreciate that various modifications and equivalent embodiments are possible without departing from the scope of the present disclosure as defined in the appended claims.

What is claimed is:

1. A device comprising:
a computing bit cell; and
a control circuit configured to control the computing bit cell,
wherein the computing bit cell comprises:
a memory cell configured to store a coefficient bit;
a first transistor that is connected between a first node and a ground node, the first transistor having a gate that is connected to a first line which extends in a first direction and which is configured to receive a voltage based on a first input bit;
a second transistor that is connected between a second node and a second line that extends in a second direction that crosses the first direction, the second transistor having a gate that is configured to receive a pre-charge enable signal, the second line being configured to receive a voltage based on a second input bit; and
a third transistor that is connected between the first node and the second node, the third transistor having a gate connected to the memory cell.

2. The device of claim 1, wherein a voltage of the first node is output to an outside the computing bit cell.

3. The device of claim 1, wherein the first transistor is an n-channel field effect transistor, and
each of the second transistor and the third transistor is a p-channel field effect transistor.

4. The device of claim 1, wherein the third transistor is connected to a first latch node of the memory cell corresponding to an inverted bit of the coefficient bit.

5. The device of claim 4, wherein the memory cell comprises:
a first inverter and a second inverter cross-coupled between the first latch node and a second latch node;
a first pass transistor connected between the first latch node and a complementary bit line; and
a second pass transistor connected between the second latch node and a bit line.

6. The device of claim 1, wherein the control circuit is configured to selectively operate the computing bit cell in a first mode and a second mode,
in the first mode, a voltage corresponding to a product of the coefficient bit and the first input bit is generated at the first node, and
in the second mode, a voltage corresponding to a product of the coefficient bit and the second input bit is generated at the first node.

7. The device of claim 6, wherein the control circuit is configured to initialize the computing bit cell in the first mode by:
pulling down the first node to a ground potential by turning on the first transistor through the first line; and
pre-charging the second node from the second line which is pulled up by turning on the second transistor through the pre-charge enable signal.

8. The device of claim 7, wherein, after initializing the computing bit cell in the first mode, the control circuit is configured to:
turn off the second transistor through the pre-charge enable signal; and
apply a voltage corresponding to an inverted bit of the first input bit to the first line.

9. The device of claim 6, wherein the control circuit is configured to pull down the first node to a ground potential by turning on the first transistor through the first line to initialize the computing bit cell in the second mode.

10. The device of claim 9, wherein, after initializing the computing bit cell in the second mode, the control circuit is configured to:
turn off the first transistor through the first line;
turn on the second transistor through the pre-charge enable signal; and
apply a voltage corresponding to the second input bit to the second line.

11. A device comprising:
a cell array; and
a control circuit configured to control the cell array,
wherein the cell array comprises:
a first computing bit cell and a second computing bit cell that are connected to a first line that extends in a first direction, the first computing bit cell and the second computing bit cell being configured to store a first coefficient bit and a second coefficient bit, respectively;
a third computing bit cell and a fourth computing bit cell that are connected to a second line that extends in the first direction, the third computing bit cell and the fourth computing bit cell being configured to store a third coefficient bit and a fourth coefficient bit, respectively;
a first adder connected to the first computing bit cell; and
a first multiplexer configured to selectively provide one of an output of the second computing bit cell and an output of the third computing bit cell to the first adder,
wherein the first computing bit cell and the third computing bit cell are connected to a third line that extends in a second direction crossing the first direction, and
the second computing bit cell and the fourth computing bit cell are connected to a fourth line that extends in the second direction.

12. The device of claim 11, wherein the control circuit is configured to set the cell array to a first mode to calculate a product of the first coefficient bit and a first input bit of which an inverted bit corresponds to a voltage applied to the first line, and a sum of the first input bit and the second coefficient bit.

13. The device of claim 12, wherein the control circuit is configured to control the first multiplexer such that the output of the second computing bit cell is provided to the first adder in the first mode.

14. The device of claim 11, wherein the control circuit is configured to set the cell array to a second mode to calculate a product of the first coefficient bit and a second input bit corresponding to a voltage applied to the third line, and a sum of the second input bit and the third coefficient bit.

15. The device of claim 14, wherein the control circuit is configured to control the first multiplexer to provide the output of the third computing bit cell to the first adder in the second mode.

16. The device of claim 11, wherein the cell array further comprises:
a second adder connected to the fourth computing bit cell; and
a second multiplexer configured to selectively provide one of the output of the third computing bit cell and the output of the second computing bit cell to the second adder.

17. A device for compute-in-memory (CIM), the device comprising:
a cell array including a plurality of computing bit cells; and
a control circuit configured to selectively operate the cell array in a first mode and a second mode,
wherein the cell array comprises a first adder circuit configured to:
in the first mode, add together outputs of a first sub-array and a second sub-array, which are adjacent to each other in a first direction, and
in the second mode, add together outputs of the first sub-array and a third sub-array, which are adjacent to each other in a second direction that crosses the first direction.

18. The device of claim 17, wherein the cell array further comprises a second adder circuit configured to:
in the first mode, add together outputs of the third sub-array and a fourth sub-array, which are adjacent to each other in the first direction, and
in the second mode, add together outputs of the second sub-array and the fourth sub-array, which are adjacent to each other in the second direction.

19. The device of claim 17, wherein each of the plurality of computing bit cells is configured to:
in the first mode, store a coefficient bit, and calculate a product of the coefficient bit and a first input bit provided through a first line that extends in the first direction, and
in the second mode, calculate a product of the coefficient bit and a second input bit provided through a second line that extends in the second direction.

20. The device of claim 19, wherein the control circuit is configured to:
apply a voltage corresponding to an inverted bit of the first input bit to the first line in the first mode; and
apply a voltage corresponding to the second input bit to the second line in the second mode.
